(19) United States
(12) Patent Application Publication
(10) Pub. No.: US 2026/0173610 A1
(43) Pub. Date: Jun. 18, 2026

(54) DISPLAY MODULE AND REPAIR METHOD FOR DISPLAY MODULE

(71) Applicant: SAMSUNG ELECTRONICS CO., LTD., Suwon-si (KR)

(72) Inventors: Soonmin CHA, Suwon-si (KR); Kyunghoon CHUNG, Suwon-si (KR); Hyeondong LEE, Suwon-si (KR); Younghoon SHIN, Suwon-si (KR); Yeseul PARK, Suwon-si (KR)

(73) Assignee: SAMSUNG ELECTRONICS CO., LTD., Suwon-si (KR)

(21) Appl. No.: 19/447,113

(22) Filed: Jan. 13, 2026

Related U.S. Application Data
(63) Continuation of application No. PCT/KR2025/021267, filed on Dec. 10, 2025.

(30) Foreign Application Priority Data
Dec. 17, 2024 (KR) 10-2024-0188486

(51) Int. Cl. H10H 29/34; H10H 29/01; H10H 29/851

(52) U.S. Cl. CPC H10H 29/34; H10H 29/0361; H10H 29/8514

(57) ABSTRACT

Provided is a display module and method of repairing same. The display module includes: a substrate including a plurality of thin film transistors; and a plurality of pixels on the plurality of thin film transistors, wherein each of the plurality of pixels includes a red light-emitting diode (LED), a green LED, and a blue LED, wherein the red LED or the green LED of at least one pixel, among the plurality of pixels, fails to illuminate, and wherein the at least one pixel includes a light conversion layer on an upper side of the blue LED of the at least one pixel.

### CROSS-REFERENCE TO RELATED APPLICATIONS

This application is a continuation application of an International Application No. PCT/KR 2025/021267, filed on Dec. 10, 2025, which is based on and claims priority to Korean Patent Application No. 10-2024-0188486, filed on Dec. 17, 2024, in the Korean Intellectual Property Office, the disclosures of which are incorporated by reference herein in their entireties.

### BACKGROUND

### 1. Field

The disclosure relates to a display module, and more particularly, to a display module in which each of a plurality of pixels is formed by a red light-emitting diode (LED), a green LED, and a blue LED, and a repair method for a display module having such a structure.

### 2. Description of Related Art

LEDs are widely used not only as a light source for lighting devices but also as a light source for displays in various electronic products, such as TVs, mobile phones, PCs, notebook PCs, wearable devices, and PDAs.

Recently, micro-LEDs measuring less than 100 μm have been developed. Compared to standards LEDs, micro-LEDs boast faster response times, lower power consumption, and higher brightness, making them attractive as next-generation display light-emitting elements.

Display modules may be manufactured by processing LED wafers into chips and then through transfer and bonding processes.

As a result of the manufacturing process, LEDs may have epitaxial defects, chip process defects, transfer and bonding defects, etc., which may later lead to defective pixels (e.g., dead pixels).

For example, a defective pixel may occur such that any one of a red LED, a green LED, and a blue LED included in a pixel does not light up when power is applied to a display module. In other words, a pixel defect may occur such that any one of the red LED, green LED, and blue LED in the pixel fails to turn on when power is applied to the display module.

### SUMMARY

A display module according to one or more embodiments of the disclosure may include: a substrate having a plurality of thin film transistors; and a plurality of pixels disposed on the plurality of thin film transistors. Each of the plurality of pixels may include a red LED, a green LED, and a blue LED. At least one pixel among the plurality of pixels, in which the red LED or the green LED fails to illuminate, may include a light conversion layer provided on an upper side of the blue LED.

According to an aspect of the disclosure, a display module includes: a substrate including a plurality of thin film transistors; and a plurality of pixels on the plurality of thin film transistors, wherein each of the plurality of pixels includes a red light-emitting diode (LED), a green LED, and a blue LED, wherein the red LED or the green LED of at least one pixel, among the plurality of pixels, fails to illuminate, and wherein the at least one pixel includes a light conversion layer on an upper side of the blue LED of the at least one pixel.

The green LED of the at least one pixel may fail to illuminate, the light conversion layer may include a green light conversion layer on the upper side of the blue LED of the at least one pixel, and the green light conversion layer may be configured to convert blue light emitted from the blue LED of the at least one pixel into green light.

The red LED of the at least one pixel may fail to illuminate, the light conversion layer may include a red light conversion layer on the upper side of the blue LED of the at least one pixel, and the red light conversion layer may be configured to convert blue light emitted from the blue LED of the at least one pixel into red light.

The light conversion layer may include one of quantum dots, perovskite, and phosphor.

The display module may further include: a protective layer on an upper side of the plurality of pixels.

The at least one pixel may further include a blue light blocking layer on an upper side of the light conversion layer.

The red LED, the green LED, and the blue LED of each of the plurality of pixels may include micro-LEDs.

According to an aspect of the disclosure, a method of repairing a display module including a plurality of pixels, each pixel of the plurality of pixels including a red light-emitting diode (LED), a green LED, and a blue LED, includes: identifying a pixel, among the plurality of pixels, in which the red LED or the green LED fails to illuminate; applying a light conversion layer to an upper side of the blue LED of the identified pixel, wherein the light conversion layer is configured to emit red light or to emit green light; curing the light conversion layer; and forming a protective layer on a portion of the identified pixel.

The method may further include: after identifying the identified pixel, locally removing an original protective layer on the upper side of the blue LED of the identified pixel.

The method may further include: applying a blue light blocking layer to an upper side of the light conversion layer after curing the light conversion layer, wherein the blue light blocking layer is configured to absorb blue light; and curing the blue light blocking layer.

The light conversion layer may be applied using ink-jet printing or electrohydrodynamic EHD printing.

The green LED of the identified pixel may fail to illuminate, and the light conversion layer may include a green light conversion layer configured to convert blue light emitted from the blue LED of the identified pixel into green light.

The red LED of the identified pixel may fail to illuminate, and the light conversion layer may include a red light conversion layer configured to convert blue light emitted from the blue LED of the identified pixel into red light.

The light conversion layer may include one of quantum dots, perovskite, and phosphor.

The red LED, the green LED, and the blue LED of each of the plurality of pixels may include micro-LEDs.

According to an aspect of the disclosure, a display module includes: a substrate; and a pixel on the substrate, wherein the pixel includes a red light-emitting diode (LED), a green LED, and a blue LED, wherein the pixel includes a light conversion layer on an upper side of the blue LED, wherein, based on the green LED failing to illuminate, the light conversion layer includes a green light conversion layer configured to convert blue light emitted from the blue LED into green light, and wherein, based on the red LED failing to illuminate, the light conversion layer includes a red light conversion layer configured to convert blue light emitted from the blue LED into red light.

The light conversion layer may include one of quantum dots, perovskite, and phosphor.

The display module may further include a protective layer on an upper side of the pixel.

The pixel may further include a blue light blocking layer on an upper side of the light conversion layer.

The red LED, the green LED, and the blue LED may be micro-LEDs.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic plan view illustrating a display module according to one or more embodiments of the disclosure;

FIG. 2 is a schematic cross-sectional view illustrating a pixel of a display module according to one or more embodiments of the disclosure;

FIG. 3 is a cross-sectional view illustrating a state in which a red LED fails to illuminate in a pixel of a display module according to one or more embodiments of the disclosure;

FIG. 4 is a cross-sectional view illustrating a state in which a pixel of a display module with a red LED which fails to illuminate is repaired according to one or more embodiments of the disclosure;

FIG. 5 is a cross-sectional view illustrating a state in which a green LED fails to illuminate in a pixel of a display module according to one or more embodiments of the disclosure;

FIG. 6 is a cross-sectional view illustrating a state in which a pixel of a display module with a green LED which fails to illuminate is repaired according to one or more embodiments of the disclosure;

FIG. 7 is a cross-sectional view illustrating a state in which a pixel of a display module with a red LED which fails to illuminate is repaired according to one or more embodiments of the disclosure;

FIG. 8 is a cross-sectional view illustrating a state in which a pixel of a display module with a green LED which fails to illuminate is repaired according to one or more embodiments of the disclosure;

FIG. 9 is a flowchart illustrating a repair method for a display module according to one or more embodiments of the disclosure;

FIGS. 10A, 10B, and 10C are views illustrating a repair method for a display module according to one or more embodiments of the disclosure;

FIG. 11 is a flowchart illustrating a repair method for a display module according to one or more embodiments of the disclosure; and

FIGS. 12A, 12B, 12C, and 12D are views illustrating a repair method for a display module according to one or more embodiments of the disclosure.

### DETAILED DESCRIPTION

One or more embodiments described herein, and terms used herein, are not intended to limit the technical features described in this disclosure to specific embodiments, but should be understood to include various modifications, equivalents, or alternatives of the one or more disclosed embodiments.

In connection with the description of the drawings, similar reference numbers may be used for similar or related components.

The singular form of a noun corresponding to an item may include one or more of the above item, unless the relevant context clearly indicates otherwise.

In this document, each of phrases such as “A or B,” “at least one of A and B,” “at least one of A or B,” “A, B, or C,” “at least one of A, B, and C,” “at least one of A, B, C” may include any one of the items listed together with the corresponding phrase, or any possible combination thereof.

The term “and/or” includes any element of a plurality of related described elements or a combination of a plurality of related described elements.

Terms such as “first,” “second,” “primary,” or “secondary” may be used simply to distinguish one component from other components, and do not limit the corresponding components in other respects (e.g., importance or order).

When a component (e.g., a first component) is said to be “coupled” or “connected” to another component (e.g., a second component), with or without the terms “functionally” or “communicatively,” it means that the component can be connected to the other component directly (e.g., wired), wirelessly, or through a third component.

Terms such as “include” or “have” are intended to designate the presence of features, numbers, steps, operations, components, parts, or combinations thereof described in the embodiment, but do not preclude the presence or addition of one or more other features, numbers, steps, operations, components, parts, or combination thereof.

When a component is said to be “connected,” “coupled,” “supported,” or “in contact” with another component, this means not only cases where the components are directly connected, coupled, supported, or contacted, but also cases where the components are indirectly connected, coupled, supported, or contacted through a third component.

When a component is said to be located “on” other component, this includes not only cases where the component is in contact with the other component, but also cases where another component exits between the two components.

Further, terms such as “leading end”, “rear end”, “upper side”, “lower side”, “upper end”, “lower end”, etc. used in the disclosure are defined with reference to the drawings. However, the shape and position of each component are not limited by these terms.

A display module manufactured according to one or more embodiments of the disclosure may include a substrate on a surface of which a thin film transistor (TFT) layer is formed; a plurality of light emitting diodes (LEDs) arranged on the TFT layer; and wiring electrically connecting circuits disposed on a rear surface of the substrate. Here, the substrate may be any one of a glass substrate, a flexible substrate and a plastic substrate, and may be referred to as a backplane.

The substrate of the display module according to one or more embodiments of the disclosure may include a rear substrate electrically connected to the rear surface of the substrate through a flexible printed circuit (FPC). Here, the rear substrate may be formed in a form of a thin film or a thin glass having a thickness of several tens of micrometers (for example, 50 μm or less). In a case that the rear substrate is formed in the form of a thin film, the rear substrate may be formed of a plastic material, for example, any one of polyimide (PI), polyethylene terephthalate (PET), polythersulfone (PES), polyethylene naphtalate (PEN) or polycabonate (PC).

In the substrate according to one or more embodiments of the disclosure, side wiring may be formed at an edge portion of the substrate, and a first connection pad and a second connection pad may be electrically connected to each other, the first connection pad being disposed at the edge portion of a front surface of the substrate and the second connection pad being disposed on the rear surface of the substrate. To this end, the side wiring may be formed along the front surface, side surface and rear surface of the substrate, and have one end electrically connected to the first connection pad and the other end electrically connected to the second connection pad. Here, a portion of the side wiring may be formed on the side surface of the substrate, and thus protrude more than the side surface of a TFT substrate by a thickness of the side wiring. In this case, the rear substrate may be electrically connected to the second connection pad through the FPC. A driver integrated circuit (DIC) mounted on the rear surface of the TFT substrate may be directly connected to the second connection pad or indirectly connected to the second connection pad through a separate wiring.

In addition, the display module of the disclosure may be used in a wearable device, a portable device, a handheld device and an electronic or electronic product requiring various displays, in a single unit. The display module may also be used in small display devices such as a monitor for a personal computer, a television (TV) and the like, and large display devices such as a digital signage, an electronic display and the like, through a plurality of assembly arrangements.

The LED referred to in the disclosure may be a semiconductor chip formed of an inorganic light emitting material and capable of emitting light by itself in case of being powered.

In addition, the LED referred to herein may be a micro-LED which has fast response speed, requires low power and has high luminance, and is thus spotlighted as a light emitting element of a next generation display. Such a micro-LED is more efficient at converting electricity into a photon than a conventional liquid crystal display (LCD) or an organic light emitting diode (OLED) display. That is, the micro-LED has higher “brightness per watt” compared to the conventional LCD or OLED display. Accordingly, the micro-LED may achieve the same brightness with about half the energy of a conventional LED (a size of the width and length exceeding 100 μm×100 μm) or the OLED display. In addition, the micro-LED may implement high resolution, excellent color, contrast and brightness and thus accurately express a wide range of colors, and may implement a clear screen even in outside bright sunlight. In addition, the micro-LED may be strong against a burn-in phenomenon and generate little heat, thereby ensuring its long life without deformation.

The disclosure may provide a display module and a method for repairing a display module, which can improve visibility by reducing or minimizing defects in a green LED and a red LED of the display module by repairing pixels without removing and reattaching the green LED or red LED when defect of the green LED or red LED resulting in the green LED or red LED failing to illuminate occurs in a pixel including a red LED, a green LED, and a blue LED.

Hereinafter, embodiments of a display module and a repair method for the display module according to the disclosure will be described in detail with reference to the accompanying drawings.

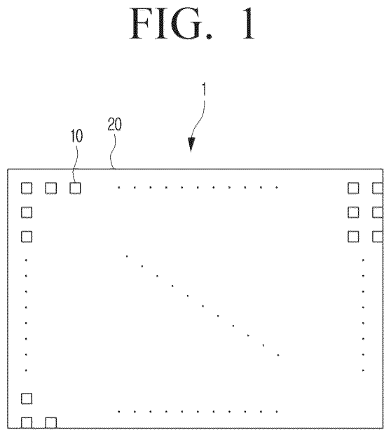

FIG. 1 is a schematic plan view illustrating a display module 1 according to one or more embodiments of the disclosure.

Referring to FIG. 1, a display module 1 may include a substrate 20 on which thin film transistors are formed, and a plurality of pixels 10 configured on the substrate 20 and electrically connected to the thin film transistors.

The display module 1 may operate as a display including the plurality of pixels 10. According to one or more embodiments, a plurality of display modules 1 may be connected to configure a single large display device. Then, the connected plurality of display modules 1 may operate as a single display.

The substrate 20 may operate the plurality of pixels 10 arranged on the substrate 20 to display information such as images, characters, etc. The substrate 20 may be configured to independently drive a red LED (light emitting diode) 11, a green LED 12, and a blue LED 13 included in the pixel 10, as described below.

According to one or more embodiments, the plurality of pixels 10 may be arranged in a matrix configuration on the substrate 20 in a first direction and a second direction perpendicular to the first direction.

However, the arrangement of the plurality of pixels 10 of the display module 1 according to one or more embodiments of the disclosure is not limited thereto. As another example, the plurality of pixels 10 may be arranged in various patterns, such as a zigzag pattern and the like.

The plurality of pixels 10 of the display module 1 according to one or more embodiments of the disclosure may have the same structure. Therefore, only one pixel 10 will be described below.

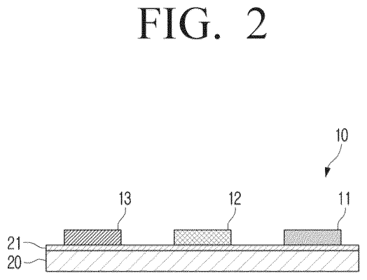

FIG. 2 is a schematic cross-sectional view illustrating a pixel 10 of a display module 1 according to one or more embodiments of the disclosure.

Referring to FIG. 2, the pixel 10 according to one or more embodiments of the disclosure may be disposed on the upper side of a thin film transistors 21.

The pixel 10 may include a red LED 11, a green LED 12, and a blue LED 13. In other words, the red LED 11, the green LED 12, and the blue LED 13 may be disposed on the upper side of the thin film transistors 21. The red LED 11 may be configured to emit red light. The green LED 12 may be configured to emit green light. The blue LED 13 may be configured to emit blue light.

The thin film transistors 21 may be configured to control the pixel 10. For example, the thin film transistors 21 may be configured to control the red LED 11, the green LED 12, and the blue LED 13 of the pixel 10, respectively. When power is applied to the pixel 10 by the thin film transistors 21, the red LED 11, the green LED 12, and the blue LED 13 may emit light.

For example, when power is applied to the red LED 11 by the thin film transistors 21, the red LED 11 may emit red light. When power is applied to the green LED 12 by the thin film transistors 21, the green LED 12 may emit green light. When power is applied to the blue LED 13 by the thin film transistors 21, the blue LED 13 may emit blue light.

The substrate 20 may be disposed below the thin film transistors 21. In other words, the thin film transistors 21 may be configured on the upper side of the substrate 20.

The substrate 20 may formed of polyimide PI, polyethylene terephthalate PET, metal foil, polyvinyl chloride PVC, polymethyl methacrylate PMMA, glass, etc.

In the display module 1 having a structure as described above according to one or more embodiments of the disclosure, a defect may occur in which one of the red LED 11, the green LED 12, and the blue LED 13 of the pixel 10 turns off.

Due to differences in spectral sensitivity among the red LED 11, the green LED 12, and the blue LED 13, the green LED 12 may have the best visibility, while the blue LED 13 may have the worst visibility. The visibility of the red LED 11 may be worse than that of the green LED 12, but better than that of the blue LED 13. Therefore, in order to improve the quality of the display module 1 when one of the green LED 12 and the red LED 11 of at least one pixel 10 among the plurality of pixels 10 fails to illuminate, the pixel 10 in which the defect occurred may be repaired so that the pixel 10 may emit green light or red light.

To this end, the display module 1 according to one or more embodiments of the disclosure may be repaired to emit red light or green light by disposing a light conversion layer 31 or 32 above the blue LED 13 of the pixel 10 in which defect of the red LED 11 or the green LED 12 has occurred.

The light conversion layer 31 or 32 disposed on above the blue LED 13 may be formed of any one of quantum dots, perovskite, and phosphor.

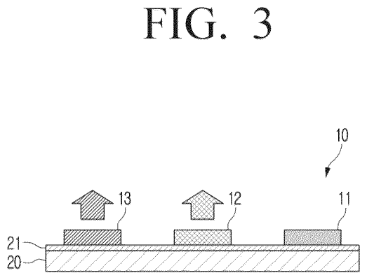

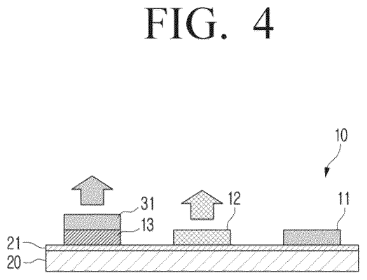

Hereinafter, with reference to FIGS. 3 and 4, a case in which the red LED 11 fails to illuminate in one pixel 10 among the plurality of pixels 10 of the display module 1 according to one or more embodiments of the disclosure and a state in which this is repaired will be described in detail.

FIG. 3 is a cross-sectional view illustrating a state in which a red LED 11 fails to illuminate in a pixel 10 of a display module 1 according to one or more embodiments of the disclosure.

Referring to FIG. 3, the blue LED 13 and the green LED 12 of the pixel 10 according to one or more embodiments of the disclosure may emit light, while the red LED 11 may not emit light. In other words, the blue LED 13 may emit blue light, and the green LED 12 may emit green light. However, the red LED 11 may not emit red light.

In this case, the visibility of the display module 1 may be reduced because red light, which has a higher visibility than blue light, is not emitted from the pixel 10. To address this problem, as illustrated in FIG. 4, the blue LED 13 may be configured to emit red light.

FIG. 4 is a cross-sectional view illustrating a state in which a pixel 10 of a display module 1 with a red LED 11 which fails to illuminate is repaired according to one or more embodiments of the disclosure.

Referring to FIG. 4, a light conversion layer 31 may be disposed on the upper side of the blue LED 13 of the pixel 10 with the red LED 11 which fails to illuminate. Then, red light may be emitted from the light conversion layer 31 disposed on the upper side of the blue LED 13.

In this case, the light conversion layer 31 may be configured as a red light conversion layer that converts blue light emitted from the blue LED 13 into red light. Then, the blue light emitted from the blue LED 13 may be incident on the red light conversion layer 31, and the incident blue light may be converted into red light while passing through the red light conversion layer 31 and then the red light may be emitted therefrom. Therefore, the pixel 10 in which a defect of the red LED 11 has occurred may emit red light using the blue LED 13 and the red light conversion layer 31.

The red light conversion layer 31 may be formed of any one of quantum dots, perovskite, and phosphor.

As illustrated in FIG. 4, when the red light conversion layer 31 is disposed on the upper side of the blue LED 13 of the pixel 10 including the red LED 11 with a defect, the pixel 10 that did not emit red light due to the red LED 11 failing to illuminate may emit red light using the blue LED 13, thereby improving the visibility of the display module 1.

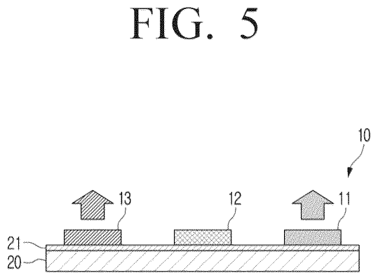

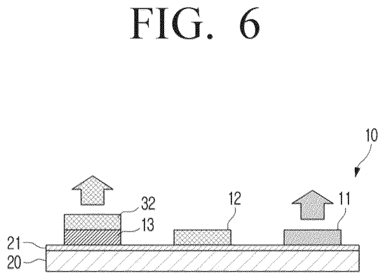

Hereinafter, with reference to FIGS. 5 and 6, a case in which the green LED 12 fails to illuminate in a pixel 10 of the display module 1 according to one or more embodiments of the disclosure and a state in which this is repaired will be described in detail.

FIG. 5 is a cross-sectional view illustrating a state in which a green LED 12 fails to illuminate in a pixel 10 of a display module 1 according to one or more embodiments of the disclosure.

Referring to FIG. 5, the blue LED 13 and the red LED 11 of a pixel 10 according to one or more embodiments of the disclosure may emit light, while the green LED 12 may not emit light. In other words, the blue LED 13 may emit blue light, and the red LED 11 may emit red light. However, the green LED 12 may not emit green light.

In this case, the visibility of the display module 1 may be reduced because the green light, which has the highest visibility, is not emitted from the pixel 10. To address this problem, as illustrated in FIG. 6, the blue LED 13 may be used to emit green light.

FIG. 6 is a cross-sectional view illustrating a state in which a pixel 10 of a display module 1 with a green LED 12 which fails to illuminate is repaired according to one or more embodiments of the disclosure.

Referring to FIG. 6, a light conversion layer 32 may be disposed on the upper side of the blue LED 13 of the pixel 10 in which the green LED 12 fails to illuminate. Then, green light may be emitted from the light conversion layer 32 disposed on the upper side of the blue LED 13.

In this case, the light conversion layer 32 may be configured as a green light conversion layer that converts blue light emitted from the blue LED 13 into green light. Then, the blue light emitted from the blue LED 13 may be incident on the green light conversion layer 32, and the incident blue light may be converted into green light while passing through the green light conversion layer 32 and then the green light may be emitted therefrom. Therefore, the pixel 10 in which a defect of the green LED 12 has occurred may emit green light using the blue LED 13 and the green light conversion layer 32.

The green light conversion layer 32 may be formed of any one of quantum dots, perovskite, and phosphor. The composition and/or structure of the green light conversion layer 32 that converts blue light into green light may be different from that of the red light conversion layer 31 that converts blue light into red light.

As illustrated in FIG. 6, when the green light conversion layer 32 is disposed on the upper side of the blue LED 13 of the pixel 10 including the green LED 12 in which a defect has occurred, the pixel 10 that did not emit green light due to the green LED 12 failing to illuminate may emit green light using the blue LED 13, thereby improving the visibility of the display module 1.

In the above, the case where mixed light is not emitted from the light conversion layers 31 and 32 by using the light conversion layers 31 and 32 having a high blue light absorption rate has been described, but the disclosure may not be limited thereto. As another example, a pixel 10 in which a defect has occurred may be repaired by using light conversion layers 31 and 32 having a low blue light absorption rate.

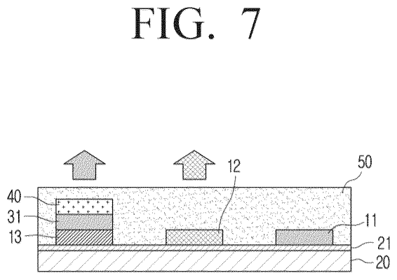

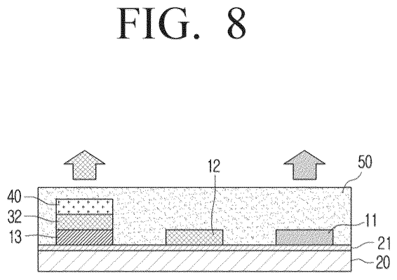

Hereinafter, a display module 1 repaired using light conversion layers 31 and 32 having a low absorption rate of blue light will be described in detail with reference to FIGS. 7 and 8.

FIG. 7 is a cross-sectional view illustrating a state in which a pixel 10 of a display module 1 with a red LED 11 which fails to illuminate is repaired according to one or more embodiments of the disclosure.

Referring to FIG. 7, a light conversion layer 31 and a blue light blocking layer (e.g., a blue-cut layer) 40 may be stacked and disposed on the upper side of the blue LED 13 of the pixel 10 with the red LED 11 which fails to illuminate. For example, the light conversion layer 31 may be disposed on the upper side of the blue LED 13, and the blue light blocking layer 40 may be disposed on the upper side of the light conversion layer 31. Then, red light may be emitted from the blue light blocking layer 40 disposed above the blue LED 13.

In this case, the light conversion layer 31 may be configured as a red light conversion layer that converts blue light emitted from the blue LED 13 into red light. Then, the blue light emitted from the blue LED 13 may be incident on the red light conversion layer 31, and the incident blue light may be converted into red light while passing through the red light conversion layer 31 and then the red light may be emitted therefrom.

However, because the red light conversion layer 31 does not have a high absorption rate of blue light, it may not convert all of the incident blue light into red light, and some of the blue light may pass through the red light conversion layer 31. For example, when the blue light absorption rate of the red light conversion layer 31 is less than about 90%, some of the incident blue light may pass through the red light conversion layer 31.

When the red light conversion layer 31 does not absorb more than 90% of the blue light emitted from the blue LED 13 as described above, mixed light, a mixture of red and blue light, may be emitted from the red light conversion layer 31. When mixed light is emitted from the pixel 10, the visibility of the display module 1 may be reduced.

To address this, the blue light blocking layer 40 may be disposed on the upper side of the red light conversion layer 31. The blue light blocking layer 40 may be configured to allow red light to pass through and block blue light.

When the blue light blocking layer 40 is disposed on the upper side of the red light conversion layer 31, blue light passing through the red light conversion layer 31, which has a low blue light absorption rate, may be blocked by the blue light blocking layer 40, allowing only red light to pass through. Therefore, only red light may be emitted from the blue light blocking layer 40.

As illustrated in FIG. 7, when the red light conversion layer 31 having low blue light absorption rate and the blue light blocking layer 40 are sequentially laminated on the upper side of the blue LED 13 of the pixel 10 including the red LED 11 in which a defect has occurred, the pixel 10 in which the red LED 11 fails to illuminate and red light is not emitted may emit red light using the blue LED 13, thereby improving the visibility of the display module 1.

FIG. 8 is a cross-sectional view illustrating a state in which a pixel 10 of a display module 1 with a green LED 12 which fails to illuminate is repaired according to one or more embodiments of the disclosure.

Referring to FIG. 8, a light conversion layer 32 and a blue light blocking layer 40 may be stacked and disposed on the upper side of the blue LED 13 of the pixel 10 with the green LED 12 which fails to illuminate. For example, the light conversion layer 32 may be disposed on the upper side of the blue LED 13, and the blue light blocking layer 40 may be disposed on the upper side of the light conversion layer 32. Then, green light may be emitted from the blue light blocking layer 40 disposed above the blue LED 13.

In this case, the light conversion layer 32 may be configured as a green light conversion layer 32 that converts blue light emitted from the blue LED 13 into green light. Then, the blue light emitted from the blue LED 13 may be incident on the green light conversion layer 32, and the incident blue light may be converted into green light while passing through the green light conversion layer 32 and then the green light may be emitted therefrom.

However, because the green light conversion layer 32 does not have a high absorption rate of blue light, it may not convert all of the incident blue light into green light, and some of the blue light may pass through the green light conversion layer 32. For example, when the blue light absorption rate of the green light conversion layer 32 is less than about 90%, some of the incident blue light may pass through the green light conversion layer 32.

When the green light conversion layer 32 does not absorb more than 90% of the blue light emitted from the blue LED 13 as described above, mixed light, a mixture of green and blue light, may be emitted from the green light conversion layer 32. When mixed light is emitted from the pixel 10, the visibility of the display module 1 may be reduced.

To address this, the blue light blocking layer 40 may be disposed on the upper side of the green light conversion layer 32. The blue light blocking layer 40 may be configured to allow green light to pass through and block blue light.

When the blue light blocking layer 40 is disposed on the upper side of the red light conversion layer 31, blue light passing through the green light conversion layer 32, which has a low blue light absorption rate, may be blocked by the blue light blocking layer 40, allowing only green light to pass through. Therefore, only green light may be emitted from the blue light blocking layer 40.

As illustrated in FIG. 8, when the green light conversion layer 32 having low blue light absorption rate and the blue light blocking layer 40 are sequentially laminated on the upper side of the blue LED 13 of the pixel 10 including the green LED 12 in which a defect has occurred, the pixel 10 in which the green LED 12 failed to illuminate and green light was not emitted may emit green light using the blue LED 13, so that the visibility of the display module 1 may be improved.

According to a display module 1 having the structure as described above according to one or more embodiments of the disclosure, when a defect of a green LED 12 or a defect of a red LED 11 occurs in at least one pixel 10 among a plurality of pixels 10 of the display module 1, the pixel 10 may be repaired without removing the green LED 12 or the red LED 11 using a laser and reattaching a new green LED or a new red LED. Therefore, the defect of the green LED 12 and the red LED 11 of the display module 1 may be reduced or minimized. As a result, the display module 1 according to one or more embodiments of the disclosure may have improved visibility.

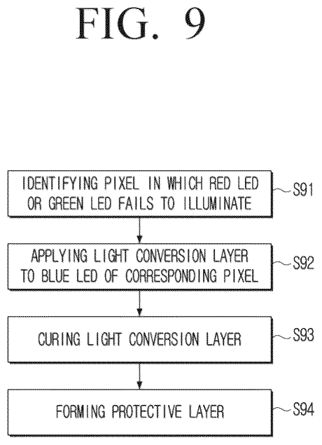

Hereinafter, a repair method of a display module 1 according to one or more embodiments of the disclosure will be described in detail with reference to FIGS. 9 to 12D.

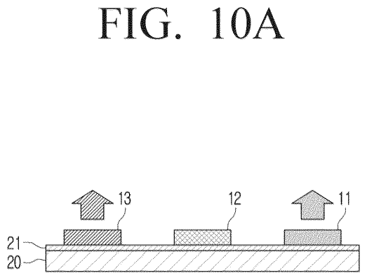

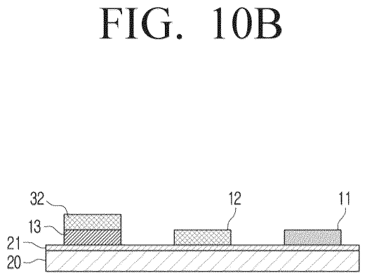

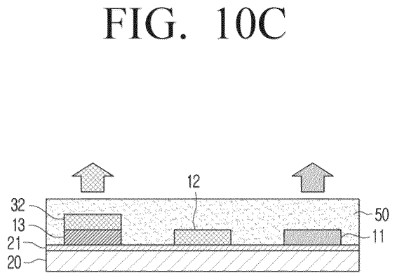

Referring to FIGS. 9 to 10C, a repair method of a display module 1 according to one or more embodiments of the disclosure, wherein the display module 1 does not have a protective layer on the upper side of a plurality of pixels 10, will be described.

FIG. 9 is a flowchart illustrating a repair method of a display module according to one or more embodiments of the disclosure. FIGS. 10A, 10B, and 10C are views illustrating a repair method of a display module according to one or more embodiments of the disclosure.

First, a pixel 10 in which a red LED 11 or a green LED 12 fails to illuminate may be identified among a plurality of pixels 10 of a display module 1 (S91). Here, the red LED 11 failing to illuminate may refer to a case in which the red LED 11 does not emit red light when power is applied to the display module 1. The green LED 12 failing to illuminate may refer to a case in which the green LED 12 does not emit green light when power is applied to the display module 1.

For example, as illustrated in FIG. 10A, the green LED 12 of the pixel 10 may fail to illuminate. In other words, when power is applied to the display module 1, the red LED 11 may emit red light and the blue LED 13 may emit blue light. However, the green LED 12 may not emit green light.

For example, the red LED 11 of the pixel 10 may fail to illuminate. In other words, when power is applied to the display module 1, the green LED 12 may emit green light and the blue LED 13 may emit blue light. However, the red LED 11 may not emit red light.

Next, a light conversion layer 31 or 32 may be applied to the upper side of the blue LED 13 of the pixel 10 in which the red LED 11 or the green LED 12 fails to illuminate (S92).

For example, when the green LED 12 of the pixel 10 fails to illuminate and the red LED 11 and blue LED 13 are turned on, a green light conversion layer 32 may be applied on the upper side of the blue LED 13 of the pixel 10, as illustrated in FIG. 10B.

For example, when the red LED 11 of the pixel 10 fails to illuminate and the green LED 12 and blue LED 13 are turned on, a red light conversion layer 31 may be applied on the upper side of the blue LED 13 of the pixel 10.

The light conversion layers 31 and 32 may be formed of any one of quantum dots, perovskite, and phosphor.

The light conversion layers 31 and 32 may be applied to the upper side of the blue LED 13 using ink-jet printing or electrohydrodynamic EHD printing.

Next, the light conversion layers 31 and 32 may be cured (S93).

Finally, as illustrated in FIG. 10C, a protective layer 50 may be formed on the upper side of the plurality of pixels 10 of the display module 1 (S94). For example, the protective layer 50 may be formed as a protective film or protective molding.

According to one or more embodiments, when the blue light absorption rate of the light conversion layers 31 and 32 is not high, a blue light blocking layer 40 may be applied to the upper side of the light conversion layers 31 and 32. For example, after curing the light conversion layers 31 and 32 applied to the upper side of the blue LED 13, the blue light blocking layer 40 may be applied on the upper side of the light conversion layers 31 and 32. Thereafter, the blue light blocking layer 40 may be cured. When curing of the blue light blocking layer 40 is completed, the protective layer 50 may be formed on the upper side of the plurality of pixels 10.

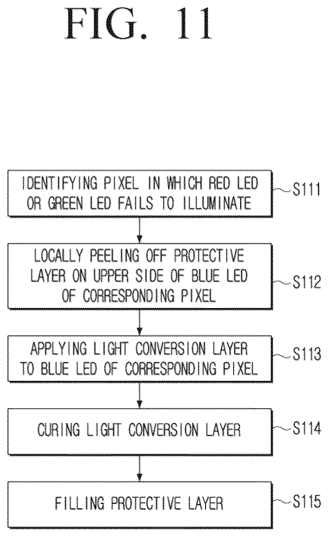

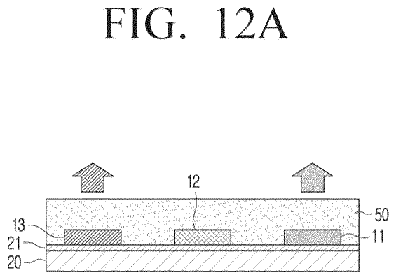

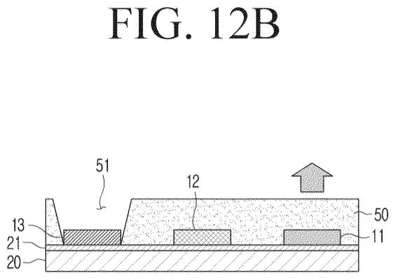

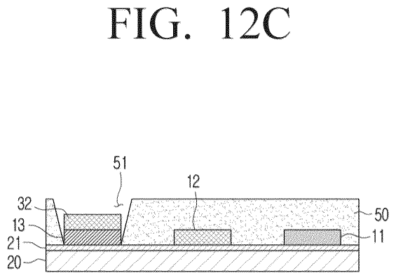

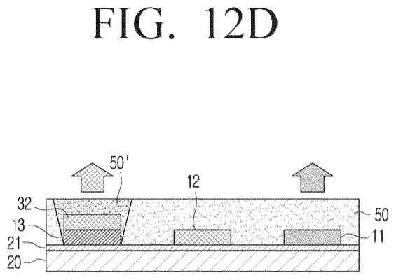

Referring to FIGS. 11 to 12D, a repair method for a display module 1 according to one or more embodiments of the disclosure, wherein a protective layer 50 is provided on the upper side of a plurality of pixels 10, will be described.

FIG. 11 is a flowchart illustrating a repair method for a display module 1 according to one or more embodiments of the disclosure. FIGS. 12A, 12B, 12C, and 12D are views illustrating a repair method for a display module 1 according to one or more embodiments of the disclosure.

First, a pixel 10 in which a red LED 11 or a green LED 12 fails to illuminate may be identified among a plurality of pixels 10 of a display module 1 (S111). Here, the red LED 11 failing to illuminate may refer to a case in which the red LED 11 does not emit red light when power is applied to the display module 1. The green LED 12 failing to illuminate may refer to a case in which the green LED 12 does not emit green light when power is applied to the display module 1.

For example, as illustrated in FIG. 12A, the green LED 12 of the pixel 10 covered with the protective layer 50 may fail to illuminate. In other words, when power is applied to the display module 1, the red LED 11 may emit red light and the blue LED 13 may emit blue light. However, the green LED 12 may not emit green light.

For example, the red LED 11 of the pixel 10 may fail to illuminate. In other words, when power is applied to the display module 1, the green LED 12 may emit green light and the blue LED 13 may emit blue light. However, the red LED 11 may not emit red light.

Next, as illustrated in FIG. 12B, the protective layer 50 on the upper side of the blue LED 13 of the corresponding pixel 10, i.e., the pixel 10 in which the red LED 11 or the green LED 12 fails to illuminate, may be locally removed (for example, it may be peeled or shaved off) (S112). In other words, the original protective layer 50 on the upper side of the blue LED 13 may be removed to form a repair space 51 in which the blue LED 13 is exposed.

Next, a light conversion layer 31 or 32 may be applied to the upper side of the blue LED 13 of the pixel 10 in which the red LED 11 or the green LED 12 fails to illuminate (S113).

For example, when the green LED 12 of the pixel 10 fails to illuminate and the red LED 11 and blue LED 13 are turned on, a green light conversion layer 32 may be applied to the upper side of the blue LED 13 of the pixel 10 through the repair space 51, as illustrated in FIG. 12C.

For example, when the red LED 11 of the pixel 10 fails to illuminate and the green LED 12 and blue LED 13 are turned on, a red light conversion layer 31 may be applied to the upper side of the blue LED 13 of the pixel 10.

The light conversion layers 31 and 32 may be formed of any one of quantum dots, perovskite, and phosphor.

The light conversion layers 31 and 32 may be applied to the upper side of the blue LED 13 using ink-jet printing or electrohydrodynamic EHD printing.

Next, the light conversion layers 31 and 32 may be cured (S114).

Finally, as illustrated in FIG. 12D, a protective layer 50′ may be filled on the upper side of the blue LED 13 of the corresponding pixel 10 (S115). In other words, the protective layer 50′ may be filled in the removed portion of the original protective layer 50, i.e., the repair space 51, over the light conversion layers 31 and 32 formed on the upper side of the blue LED 13 of the corresponding pixel 10.

According to one or more embodiments, when the blue light absorption rate of the light conversion layers 31 and 32 is not high, a blue light blocking layer 40 may be applied to the upper side of the light conversion layers 31 and 32. For example, after curing the light conversion layers 31 and 32 applied to the upper side of the blue LED 13 of the corresponding pixel 10, the blue light blocking layer 40 may be applied to the upper side of the light conversion layers 31 and 32. Thereafter, the blue light blocking layer 40 may be cured. When curing of the blue light blocking layer 40 is completed, the protective layer 50′ may be filled in the repair space 51 on the upper side of the blue LED 13 of the corresponding pixel 10.

According to the repair method for display module 1 according to one or more embodiments of the disclosure described above, when a defect of the green LED 12 or a defect of the red LED 11 occurs in at least one pixel 10 among a plurality of pixels 10 of the display module 1, the light conversion layers 31 and 32 may be applied to the upper side of the blue LED 13 of the corresponding pixel 10, thereby enabling the pixel 10 to emit the green light or red light that was not emitted. Therefore, the repair method for the display module 1 according to one or more embodiments of the disclosure may repair the pixel 10 without removing the green LED 12 or the red LED 11 using a laser and reattaching a new green LED or a new red LED. Accordingly, the defect of the green LED 12 or the red LED 11 of the display module 1 may be reduced or minimized. As a result, the visibility of the display module 1 may be improved by the repair method of the display module 1 according to one or more embodiments of the disclosure.

The above description describes a case where each of the plurality of pixels 10 of the display module 1 includes a red LED 11, a green LED 12, and a blue LED 13. However, the disclosure is not limited thereto. Each of the plurality of pixels 10 of the display module 1 may be configured to include a red micro-LED, a green micro-LED, and a blue micro-LED.

In the foregoing, the disclosure has been shown and described with reference to one or more embodiments. However, it is understood by those skilled in the art that various changes may be made in form and detail without departing from the scope of the disclosure as defined by the appended claims and equivalents thereof.

What is claimed is:

1. A display module comprising:
a substrate comprising a plurality of thin film transistors; and
a plurality of pixels on the plurality of thin film transistors,
wherein each of the plurality of pixels comprises a red light-emitting diode (LED), a green LED, and a blue LED,
wherein the red LED or the green LED of at least one pixel, among the plurality of pixels, fails to illuminate, and
wherein the at least one pixel comprises a light conversion layer on an upper side of the blue LED of the at least one pixel.

2. The display module of claim 1, wherein the green LED of the at least one pixel fails to illuminate,
wherein the light conversion layer comprises a green light conversion layer on the upper side of the blue LED of the at least one pixel, and
wherein the green light conversion layer is configured to convert blue light emitted from the blue LED of the at least one pixel into green light.

3. The display module of claim 1, wherein the red LED of the at least one pixel fails to illuminate,
wherein the light conversion layer comprises a red light conversion layer on the upper side of the blue LED of the at least one pixel, and
wherein the red light conversion layer is configured to convert blue light emitted from the blue LED of the at least one pixel into red light.

4. The display module of claim 1, wherein the light conversion layer comprises one of quantum dots, perovskite, and phosphor.

5. The display module of claim 1, further comprising:
a protective layer on an upper side of the plurality of pixels.

6. The display module of claim 1, wherein the at least one pixel further comprises a blue light blocking layer on an upper side of the light conversion layer.

7. The display module of claim 1, wherein the red LED, the green LED, and the blue LED of each of the plurality of pixels comprise micro-LEDs.

8. A method of repairing a display module including a plurality of pixels, each pixel of the plurality of pixels including a red light-emitting diode (LED), a green LED, and a blue LED, the method comprising:
identifying a pixel, among the plurality of pixels, in which the red LED or the green LED fails to illuminate;
applying a light conversion layer to an upper side of the blue LED of the identified pixel, wherein the light conversion layer is configured to emit red light or to emit green light;
curing the light conversion layer; and
forming a protective layer on a portion of the identified pixel.

9. The method of claim 8, further comprising:
after identifying the identified pixel, locally removing an original protective layer on the upper side of the blue LED of the identified pixel.

10. The method of claim 8, further comprising:
applying a blue light blocking layer to an upper side of the light conversion layer after curing the light conversion layer, wherein the blue light blocking layer is configured to absorb blue light; and
curing the blue light blocking layer.

11. The method of claim 8, wherein the light conversion layer is applied using ink-jet printing or electrohydrodynamic EHD printing.

12. The method of claim 8, wherein the green LED of the identified pixel fails to illuminate, and
wherein the light conversion layer comprises a green light conversion layer configured to convert blue light emitted from the blue LED of the identified pixel into green light.

13. The method of claim 8, wherein the red LED of the identified pixel fails to illuminate, and wherein the light conversion layer comprises a red light conversion layer configured to convert blue light emitted from the blue LED of the identified pixel into red light.

14. The method of claim 8, wherein the light conversion layer comprises one of quantum dots, perovskite, and phosphor.

15. The method of claim 8, wherein the red LED, the green LED, and the blue LED of each of the plurality of pixels comprise micro-LEDs.

16. A display module comprising:
a substrate; and
a pixel on the substrate,
wherein the pixel comprises a red light-emitting diode (LED), a green LED, and a blue LED,
wherein the pixel comprises a light conversion layer on an upper side of the blue LED,
wherein, based on the green LED failing to illuminate, the light conversion layer comprises a green light conversion layer configured to convert blue light emitted from the blue LED into green light, and
wherein, based on the red LED failing to illuminate, the light conversion layer comprises a red light conversion layer configured to convert blue light emitted from the blue LED into red light.

17. The display module of claim 16, wherein the light conversion layer comprises one of quantum dots, perovskite, and phosphor.

18. The display module of claim 16, further comprising a protective layer on an upper side of the pixel.

19. The display module of claim 16, wherein the pixel further comprises a blue light blocking layer on an upper side of the light conversion layer.

20. The display module of claim 16, wherein the red LED, the green LED, and the blue LED are micro-LEDs.
